(19) United States
(12) Patent Application Publication
(10) Pub. No.: US 2014/0319994 A1
(43) Pub. Date: Oct. 30, 2014

(54) Flourine and HF Resistant Seals for an Ion Source

(71) Applicants: Neil K. Colvin, Merrimac, NH (US); Tseh Jen Hsieh, Rowley, MA (US)

(72) Inventors: Neil K. Colvin, Merrimac, NH (US); Tseh Jen Hsieh, Rowley, MA (US)

(21) Appl. No.: 13/870,425

(22) Filed: Apr. 25, 2013

(51) Int. Cl. H01J 37/317; F16J 15/02; H01J 37/30

(52) U.S. Cl. CPC H01J 37/3171; H01J 37/3002; F16J 15/02
USPC 313/231.71; 277/314; 277/626

(57) ABSTRACT

An exemplary ion source for creating a stream of ions has a chamber body that at least partially bounds an ionization region of the arc chamber. The arc chamber body is used with a hot filament arc chamber housing that either directly or indirectly heats a cathode to sufficient temperature to cause electrons to stream through the ionization region of the arc chamber. Electrically insulating seal element(s) engaging an outer surface of the arc chamber body are provided for impeding material from exiting the chamber interior openings of the arc chamber body. The seal element(s) have a ceramic body that includes an outer wall that abuts the arc chamber body along a circumferential outer lip. The seal also has one or more radially inner channels bounded by one or more inner walls spaced inwardly from the outer wall. The electrically insulating seal element comprises a Boron Nitride (BN) material.

### FIELD OF THE INVENTION

The present invention relates to an ion implanter having an ion generating source that emits ions to form an ion beam for ion implantation of ions treatment of a workpiece.

### BACKGROUND ART

Ion implanters are used to treat silicon wafers by bombardment of the wafers with an ion beam. One use of such beam treatment is to selectively implant the wafers with impurities of a specified dopant material, at a predetermined energy levels, and in controlled concentration, to produce a semiconductor material during fabrication of a integrated circuits.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are implanted with ion in the wafer processing device.

Batch-type ion implanters are known, which typically include a spinning disk support for moving multiple silicon wafers through the ion beam. The ion beam impacts the wafer surface as the support rotates the wafers through the ion beam. Serial-type ion implanters are also known, which treat one wafer at a time. The wafers are supported in a cassette and are withdrawn one at time and placed on a support. The wafer is then oriented in an implantation orientation so that the ion beam strikes the single wafer. These serial implanters use beam shaping electronics to deflect the beam from its initial trajectory and often are used in conjunction with co-ordinated wafer support movements to selectively dope or treat the entire wafer surface.

Ion sources that generate the ion beams used in existing implanters are typically referred to as arc ion sources and can include heated filament cathodes for creating ions that are shaped into an appropriate ion beam for wafer treatment. U.S. Pat. No. 5,497,006 to Sferlazzo et al concerns an ion source having a cathode supported by a base and positioned with respect to a gas confinement chamber for ejecting ionizing electrons into the gas confinement chamber. The cathode of the '006 patent is a tubular conductive body having an endcap that partially extends into the gas confinement chamber. A filament is supported within the tubular body and emits electrons that heat the endcap through electron bombardment, thereby thermionically emitting ionizing electrons into the gas confinement chamber.

U.S. Pat. No. 5,763,890 to Cloutier et al also discloses an arc ion source for use in an ion implanter. The ion source includes a gas confinement chamber having conductive chamber walls that bound a gas ionization zone. The gas confinement chamber includes an exit opening to allow ions to exit the chamber. A base positions the gas confinement chamber relative to structure for forming an ion beam from ions exiting the gas confinement chamber.

Examples of desired dopant elements of which the source gas is comprised include: boron (B); germanium (Ge); phosphorus (P); and silicon (Si). The source gas may also include, for example, a fluorine-containing gas, such as boron trifluoride (BF₃), germanium tetrafluoride (GeF₄), phosphorous trifluoride (PF₃), or silicon tetrafluoride (SiF₄), amongst others.

It has been found that these fluorine-containing gases are particularly toxic in the gas confinement chamber environment. US Patent Application Publication No. 2012/0119113 discloses concepts to facilitate ion implantation processes by providing a method for improving performance of an ion source in an ion implanter in which at least one co-gas is introduced into an ion source chamber together with a fluorine-containing dopant source gas, the co-gas reacting with dissociated and ionized fluorine constituents of the source gas to reduce damage to the ion source chamber and increase ion source lifetime. By contrast, the present invention is directed toward providing components comprising a particular fluorine resistant material to prevent etching thereof by the fluorine, and also to prevent the formation of resultant contaminant particles that are typically undesirably transported with the ion beam to the wafer.

### SUMMARY

The following presents a simplified summary of the present invention in order to provide a basic understanding of one or more aspects thereof. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present disclosure concerns an arc ion source of a “hot type” or arc based “Bernas” or Freeman-type” or IHC (indirectly heated cathode) ion source.

One embodiment or the arc ion source includes an arc chamber body having a chamber interior bound by chamber walls for providing a confined region for generating ions from a source gas within the confined region and having an exit through which ions exit the arc chamber body. The arc chamber body has an access opening passing through a wall of the chamber body through which gas ionization energy is routed to the confined region.

A cathode supported in relation to the chamber interior injects ionizing electrons into the confined region with energy for ionizing gas in the chamber interior. An electrically insulating seal engages an outer surface of the arc chamber body to impede material from exiting the chamber interior through the access opening of the arc chamber body. The electrically insulating seal comprises a ceramic body made of, or including, a Boron Nitride (BN) material or composition.

In accordance with one embodiment of the present invention, an ion source for use in an ion implantation system is provided, comprising: an arc chamber body having a chamber interior bound by chamber walls providing a confined region for generating ions from a source gas within the confined region and having an exit through which ions exit the arc chamber body, the arc chamber body including an access opening passing through a wall of the chamber body for routing ion source components and/or ionization energy from outside the arc chamber to the chamber interior; a cathode situated in the access opening and supported in relation to the chamber interior for injecting ionizing electrons into the confined region for ionizing the source gas in the arc chamber when energized; and an electrically insulating seal element engaging an outer surface of the arc chamber body for impeding material from exiting the chamber interior through the access opening of the arc chamber body; wherein the electrically insulating seal element comprises Boron Nitride (BN) material.

In accordance with another embodiment of the present invention, a method for sealing an ion source for use in an ion implanter is provided, comprising the steps of: generating ions in a chamber interior having an exit for allowing ions generated inside the chamber interior to exit an arc chamber body; supporting a cathode within a cathode opening in spaced relation to chamber walls bounding the chamber interior for injecting ionizing electrons for movement through the chamber interior; and sealing an outer surface of the arc chamber body for impeding material from exiting the chamber through a cathode opening in the arc chamber body by providing a ceramic body having a wall that abuts the arc chamber body and further defines one or more radially inner channels bounded by one or more inner walls spaced from a region occupied by a cathode support; wherein the ceramic body comprises Boron Nitride (BN) material.

In accordance with yet another embodiment of the present invention, a seal element is provided for impeding gas flow from an arc chamber, comprising: a ceramic body including a bounding wall having an outer surface for abutting an arc chamber body along a sealing surface and which bounds a throughpassage extending through the ceramic body for routing electrode energization signals into the arc chamber; and one or more interior walls that define a cavity in the ceramic body and which communicates with a portion of an arc chamber interior and collects material in the arc chamber interior, wherein the ceramic body comprises Boron Nitride (BN) material.

Further features of the present invention will become apparent to those skilled in the art to which the present invention relates from a reading the following specification with reference to the accompanying drawings.

### BRIEF DESCRIPTION OF THE DRAWINGS

FIG. 1 is schematic view of an ion implanter for ion beam treatment of a workpiece such as a silicon wafer mounted on a spinning support;

FIG. 2 is a perspective view of an exemplary ion source constructed in accordance with the present invention;

FIG. 3 is an elevation view of an ion source constructed in accordance with the present invention;

FIG. 4 is an elevation view of the ion source illustrated in FIG. 3, as seen from the plane 4-4 thereof; and

FIGS. 5 and 6 are enlarged perspective views of seals constructed in accordance with the present invention.

### EXEMPLARY EMBODIMENT FOR PRACTICING THE INVENTION

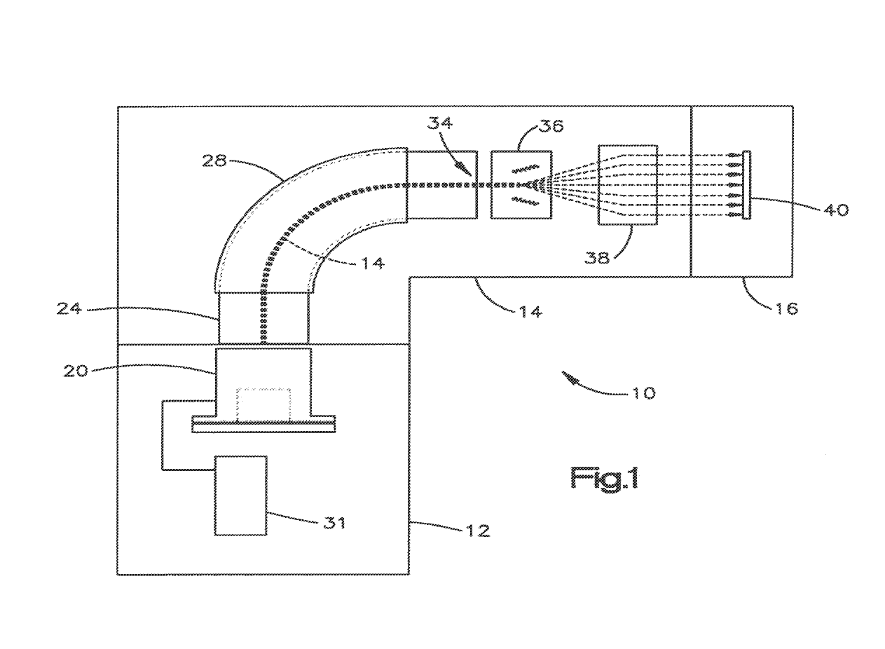

Turning to the drawings, FIG. 1 is a schematic depiction of an ion beam implanter 10. The implanter includes an ion source 12 for creating ions that form an ion beam 14, which is shaped and selectively deflected to traverse a beam path to an ending position, shown herein as implantation station 20. The implantation station includes a vacuum or implantation chamber 22 defining an interior region in which a workpiece such as a semiconductor wafer is positioned for implantation by ions that make up the ion beam 14.

The ions in the ion beam 14 tend to diverge as the beam traverses a region between the source and the implantation chamber. To reduce this divergence, the region is maintained at low pressure by one or more vacuum pumps 27 in fluid communication with the ion beam path.

The ion source 12 includes a plasma or arc chamber defining an interior region into which source materials are injected. The source materials may include an ionizable gas or vaporized source material. Ions generated within the plasma chamber are extracted from the chamber by ion beam extraction assembly 28, which includes a number of metallic electrodes for creating an ion accelerating electric field.

Positioned along the beam path 14 is an analyzing magnet 30 which bends the ion beam 14 and directs the ions through a beam neutralizer 32. The beam neutralizer injects electrons into the beam and impedes beam blow up thereby enhancing the ion transfer efficiency of the system. Downstream form the neutralizer 32, the beam 14 passes through a resolving aperture 36 which is an aperture plate which defines a minimum beam waist. The ion beam 14 that exits the resolving aperture is of an appropriate size and shape for the application.

A workpiece support 40 known as a wafer clamp or chuck is seen positioned in relation to a port 42 in fluid communication with a pump (not shown). A wafer is electrostatically attracted to the support 40 as it rests in the x-z plane which then rotates the wafer up into the beam for movement up and down and from side to side with respect to the ion beam 14. The sequence of movements is such that an entire implantation surface of the workpiece is uniformly implanted with ions. A typical application treats a wafer to dope the wafer with controlled concentrations of dopant ions.

In a typical implantation operation, undoped workpieces (typically semiconductor wafers) are retrieved from one of a number of cassettes by a robot outside the chamber which move a workpiece which has been oriented to a proper orientation in the implantation chamber 22. The robotic arm of the chamber robot grasps the workpiece, brings it within the implantation chamber 22 and places it on an electrostatic clamp or chuck of the workpiece support structure.

### Ion Source

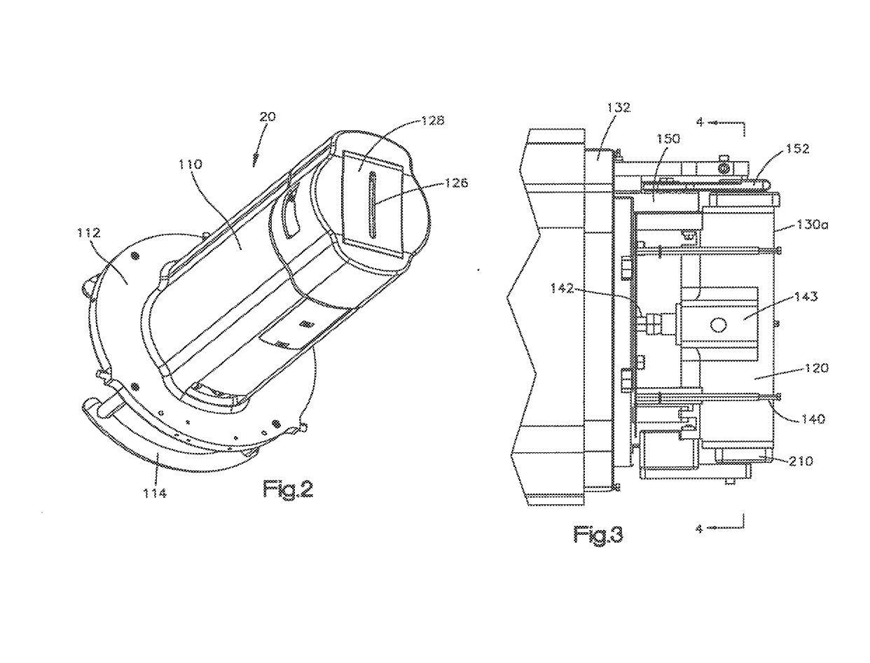

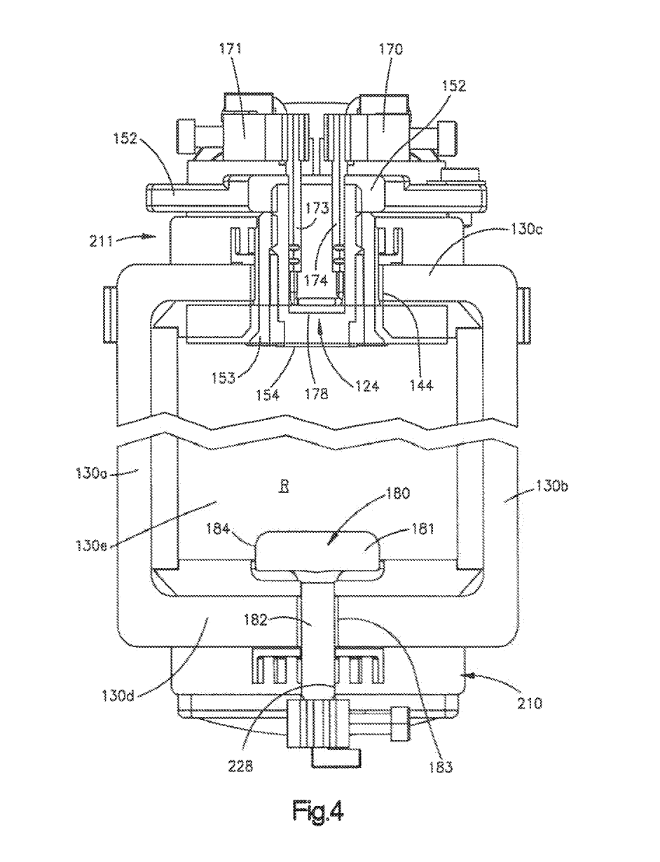

The ion generating source 20 (FIG. 2) includes a source block 110 supported by a flange 112 having handles 114 by which the source 20 can be removed from the implanter. The source block 110 supports a plasma arc chamber 120 (FIG. 3) and an electron emitting cathode 124 (FIG. 4) that, in the preferred embodiment of the invention, is supported by the source block but electrically isolated from the arc chamber 120. The illustrated ion source is known as a so-called Indirectly Heated Cathode type (IHC), which is described in much greater detail in commonly assigned U.S. Pat. No. 5,497,006, the disclosure of which shall be incorporated by reference herein.

An elongated, generally elliptically shaped exit aperture 126 in a plate 128 provides an exit for ions emitted from the source. Additional details concerning one prior art ion source are disclosed in U.S. Pat. No. 5,026,997 to Benveniste et al. assigned to the assignee of the present invention and which is incorporated herein by reference. As ions migrate from the arc chamber 120, they are accelerated away from the arc chamber 120 by electric fields set up by a beam extraction assembly (not shown) positioned relative to the exit aperture.

A source magnet (not shown) encircles the plasma arc chamber 120 to confine the plasma generating electrons to tightly constrained travel paths within the chamber 120. The source block 110 can further define cavities that accommodate vaporizer ovens that can be filled with vaporizable solids such as arsenic that are vaporized to a gas and then injected into the plasma chamber by means of delivery nozzles.

The plasma arc chamber is an elongated metal casting which defines an interior ionization region R (FIG. 4) bounded by two elongated side walls 130a, 130b top and bottom walls 130c, 130d, a rear wall 130e, and the front plate 128. These walls are covered by molybdenum or tungsten liners 134 that are periodically replaced as they are eroded and or covered with source material during use.

Extending outwardly near a front of the source block is a support flange 132, which supports the arc chamber 120. In addition, four pins 140 extend through openings 141 in the four corners of the flange 132 to support the plate 128 and position the exit aperture 126. Springs (not shown) can be used to bias the plate 128 into engagement with the arc chamber 120.

Source gas, which can be provided in the form of vaporized material is injected into the interior of the plasma arc chamber 120 from the support block 110 by a delivery tube 142 that routes the source gas into the chamber interior by a gas connection manifold 143 coupled to the side of the arc chamber. Alternatively, the source gas can be directly routed into the arc chamber interior region R by means of a port or opening (not shown) in a rear wall 130e of the chamber. In such an arrangement, a nozzle (not shown) may be included to inject the source gas or vaporized material directly into the arc chamber from a source or supply external to the ion source.

A typical ion source has an arc chamber, a cathode, a repeller, and a gas inlet passageway or delivery tube and an extraction opening, all of which require a respective opening in a wall of the chamber for access to the interior of the arc chamber. As is known in the prior art, the arc chamber typically defines at least four openings in the chamber walls: a first opening where ions can be extracted from the plasma inside the chamber; a second opening where source material (gas or vaporized material) is routed into the chamber fro ionization thereof; a third opening for receiving the cathode and providing thermal and electrical isolation between the chamber and the cathode; and a forth opening for receiving the repeller and providing thermal and electrical isolation between the repeller and the chamber. It is desirable to provide seal elements adjacent these third and forth openings to reduce gas and plasma leakage therefrom them, such that gas usage can be reduced and the surrounding areas adjacent the arc chamber can be more clean. The present invention is directed to improvements to theses seal elements.

An end wall 130c defines an opening 144 sized to allow the cathode 124 to extend into an interior of the plasma arc chamber without touching the chamber wall 130c that defines the opening 144. The cathode 124 is supported by an insulating mounting block 150 that is attached to the source block in relation to the end of the arc chamber that supports the cathode 124. A cathode body that fits into the opening 144 is mounted to a mounting plate 152 supported by the insulating mounting block 150. The insulating block 150 is an elongated ceramic electrically insulating block, typically constructed from 99% pure alumina (Al₂O₃).

The generally tubular cathode is typically constructed of tungsten and has an open end that threadingly engages to the mounting plate 152. A molybdenum shield 153 has a threaded lower end portion that threadingly engages the outer surface of the cathode. An end cap 154 of the cathode 124 is conductive and is also made from a tungsten material. The cap 154 fits within a counterbore of an end of one of the tubular cathode body. The length of the tubular member of the cathode causes the end cap 154 to extend into the arc chamber to a position approximately co-planar with the end of the shield 153.

Two conductive mounting arms 170, 171 support a filament 178 inside the cathode 124. The arms 170, 171 are attached directly to the insulating block 150 by connectors 172 that pass through the arms to engage threaded openings in the block 150. Conductive clamps 173, 174 are coupled to the filament and energized by signals routed through electrical feedthroughs connected to the arms.

Two clamps fix a tungsten filament 178 within a cavity defined by an innermost tubular member of the cathode. The filament 178 is made of a tungsten wire bent to form a helical loop. Ends of the filament 178 are supported by tantalum legs held in electrical contact with the two arms 170, 171 by the clamps 173, 174.

When the tungsten wire filament 178 is energized by application of a potential difference across the two arms 170, 171, the filament emits electrons which accelerate toward and impact the end cap 154 of the cathode 124. When the end cap 154 is sufficiently heated by electron bombardment, it in turn emits electrons into the arc chamber. The highly energetic electrons strike gas molecules in the region R and create ions within the arc chamber. An ion plasma is created and ions within this plasma exit the opening 126 to form the ion beam. The end cap 154 shields the filament from contact with the ion plasma within the chamber and extends the life of the filament.

Electrons generated by the cathode 124 that are emitted into the arc chamber but which do not engage a gas molecule within a gas ionization zone move to the vicinity of a repeller 180. The repeller 180 deflects electrons back into a gas ionization region R to contact a gas molecule. The repeller 180 is typically made from molybdenum or tungsten and includes a widened end cap 181 coupled to an elongated stem 182.

The stem is spaced from the wall 130d of the plasma arc chamber 120 by a gap defined by a cylindrical opening 183 having an inner diameter larger than the outer diameter of the repeller's stem 182. The cathode 124 and repeller 180 are therefore both electrically isolated from the arc chamber walls. Cathode and repeller can be made from either tungsten of molybdenum, but must be matched materials

The walls of the chamber 120 are held at a local ground or reference electric potential. The cathode, including the cathode end cap 154, is held at a potential of between 50-150 volts below the local ground of the chamber walls. This electric potential is coupled to the plate 152 by a power feedthrough for attaching an electrical conductor to the plate 152 that supports the cathode.

The filament 178 is held at a voltage of between 200 and 600 volts below that of the end cap 154. This large voltage difference between the filament and the cathode imparts a high energy to the electrons leaving the filament sufficient to heat the end cap 164 and thermionically emit electrons into the chamber 120. The repeller 180 is held at cathode potential by a conductive strap connecting both repeller and cathode to a common DC power supply (not shown). Another option is to connect the two to a separate DC power supply and set at an independent voltage level. The repeller 180 is supported by a repeller clamp 190 (molybdenum) mounted to a ceramic insulator 192 most preferably constructed from 96% aluminum oxide.

### Seals 210, 211

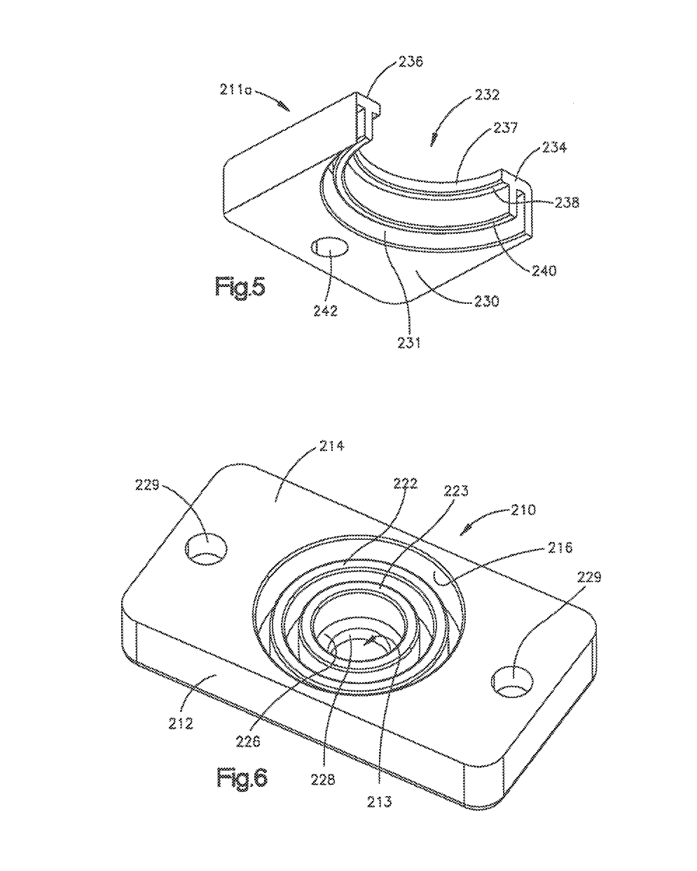

As illustrated in FIG. 4, the ion source also includes two ceramic seals elements 210, 211, each situated at opposite sides of the ion source, adjacent the cathode 124 and repeller 180, respectively. These seals elements, illustrated in greater detail in FIGS. 5 and 6, are used to prevent gas from being emitted from the arc chamber in the region of the repeller 180 and the cathode 124.

As disclosed in commonly assigned U.S. Pat. No. 7,655,930, these seal elements have typically been manufactured from aluminum oxide (Al₂O₃), preferably of approximately 96% purity. However, in accordance with the present invention, the inventors have found that seal elements constructed from Al₂O₃ tend to fail rapidly when fluorine containing gases are used in the environment of the arc chamber. For example, examples of desired source gases may include, for example, a fluorine-containing gas, such as boron trifluoride (BF₃), germanium tetrafluoride (GeF₄), phosphorous trifluoride (PF₃), or silicon tetrafluoride (SiF₄), amongst others. In addition, It has been found that these fluorine-containing gases are particularly toxic in the gas confinement chamber environment. US Patent Application Publication No. 2012/0119113 discloses concepts to facilitate ion implantation processes by providing a method for improving performance of an ion source in an ion implanter in which at least one co-gas is introduced into an ion source chamber together with a fluorine-containing dopant source gas, the co-gas reacting with dissociated and ionized fluorine constituents of the source gas to reduce damage to the ion source chamber and increase ion source lifetime.

The present inventors have discovered, through the present invention, that providing components comprising a particular fluorine resistant material to prevent etching thereof by the fluorine, and also to prevent the formation of resultant contaminant particles that are typically undesirably transported with the ion beam to the wafer. Specifically, the present invention is directed to providing seal elements in an ion source, wherein the seals are made of a hot-pressed Boron Nitride (BN) material. BN is available in standard and custom hot-pressed shapes and has several unique characteristics and physical properties which make it valuable for solving problems in a wide range of industrial applications. BN is inorganic, inert, non-reactive with halide salts and reagents, and is not wet by most molten metals and slags. These characteristics, combined with low thermal expansion and good dielectric constants make it ideal for the gas sealed interface materials used in high temperature arc ion sources and processes. While it is known that ceramic BN has several applications, the inventors have discovered that BN is ideal for ion source applications not only due to its high temperature applications, but more importantly due to the ability of the material to resist oxidation, fluorine and the entire corrosive environment in ion implantation applications.

Preferably, a high density, high purity, low porosity, hot pressed Boron Nitride ceramic is used. Hot-pressed BN is compacted at temperatures up to 2000° C. and pressures up to 2000 psi to form a dense, strong engineering material that is easily machined. The table below delineates the preferred material properties of the Hot-pressed BN ceramic:

| | | |
|---|---|---|
| Metric | English | Comments |

Physical Properties

| | | | |
|---|---|---|---|
| Density | 1.95 g/cc | 0.0704 lb/in³ | typical |
| Water Absorption | 0.6% | 0.6% | 400 hours, 100% |
| | | | RH |

| | | |
|---|---|---|
| Open Porosity | 13% | 13% |

Mechanical Properties

| | | | |
|---|---|---|---|
| Hardness, Knoop | 16 | 16 | 100 g |
| Modulus of Elasticity | 20.6 GPa | 2990 ksi | Perpendicular to |
| | | | pressing direction |
| Modulus of Elasticity | 48.2 GPa | 6990 ksi | Parallel to pressing |
| | | | direction |
| Flexural Strength | 17.2 MPa | 2490 psi | Perpendicular to |
| | | | pressing direction |
| Flexural Strength | 20.6 MPa | 2990 psi | Parallel to pressing |
| | | | direction |
| Compressive Yield | 41.3 MPa | 5990 psi | Parallel to pressing |
| Strength | | | direction |
| Compressive Yield | 51.7 MPa | 7500 psi | Perpendicular to |
| Strength | | | pressing direction |

Electrical Properties

| | | |
|---|---|---|
| Electrical Resistivity | Min 1e+015 ohm-cm | Min 1e+015 ohm-cm |

| | | | |
|---|---|---|---|
| Dielectric Constant | 4.1 | 4.1 | 1 MHz |

| | | |
|---|---|---|
| Dielectric Strength | 54 kV/mm | 1370 kV/in |

Thus, in accordance with the present invention, the exemplary seals 210, 211 include a ceramic body comprised of Boron Nitride (BN), preferably a high density, high purity, low porosity, hot pressed Boron Nitride ceramic. As illustrated in FIG. 6, the seal 210 situated in the region of the repeller 180 is a one piece ceramic body 212 that defines a center opening 213 sized to accommodate the support stem 182 of the repeller. A wall 214 that abuts the chamber source body surrounds a circumferential well or cavity 216. The seal 210 also defines two channels 220, 221 bounded by curved, generally cylindrical inner walls 222, 223 having generally circular edges that are slightly recessed from the plane of the wall 214. In the exemplary embodiment the edges of these walls are recessed a distance of about 1.37 mm from the interface between the seal and the chamber wall. These walls are spaced from each by generally equal width channels that extend into the body of the seal. A ledge 226 that surrounds the central opening 213 is approximately co-planar with a bottom or base of the channels bounded by the walls 222, 223. A surface 228 radially inward from the ledge has an inner diameter only slightly larger than the outer diameter of the repeller stem so that the ledge 226 contacts the repeller stem 182 when installed. The seal 210 defines two openings 229 that accommodate two mounting connectors 250, 252 made from molybdenum. These connectors are most preferably bolts having heads that seat in the body of the seal and extend through the seal wherein a nut (also molybdenum) tightens over a threaded end of the bolt. These are installed before the internal liners are added to the chamber interior.

The exemplary seal 211 situated in the region of the cathode 124 is a two piece ceramic body. One portion 211a of the seal 211 is depicted in FIG. 6. The seal 211 defines a larger opening 232 sized to accommodate the cathode structure. A wall 230 abuts the chamber body surrounds a circumferential well 231. The seal 211 defines a single channel bounded by a single curved, generally cylindrical inner wall 240 having a rim or edge that is slightly recessed from the plane of the wall 230. The two halves of the seal are mirror images of each other and mate along abutting surfaces 234, 236 when the seal 211 is connected to the arc source body. An inwardly facing surface 237 of the seal 211 engages an outer surface of the cathode shield. This surface bounds a ledge 238 having the same thickness as the base of the circumferential well 231. An opening 242 extends through the seal 211a and allows a connector 260 to connect the seal 211 to the arch chamber body.

Surfaces of the seal elements that are exposed to the ion plasma inside the region R of the chamber will, during use, become etched by fluorine containing gases used in the ion source. This etching phenomenon also results in sputtering of the material making up the seal elements, wherein the sputtered material is undesirably transported with the ion beam, typically causing contamination of the target workpiece. The use of Born Nitride in accordance with the present invention mitigates the fluorine induced etching and prevents or reduces contamination of the target workpiece.

From the above description of a preferred embodiment of the invention, those skilled in the art will perceive improvements, changes and modifications. Such improvements, changes and modifications within the skill of the art are intended to be covered by the appended claims.

1. An ion source for use in an ion implantation system, comprising:
an arc chamber body having a chamber interior bound by chamber walls providing a confined region for generating ions from a source gas within the confined region and having an exit through which ions exit the arc chamber body, said arc chamber body including at least one access opening passing through a wall of the chamber body for routing ion source components from outside the arc chamber to the chamber interior;
a cathode situated in the at least one access opening and supported in relation to the chamber interior for injecting ionizing electrons into the confined region of said arc chamber for ionizing the source gas therein when energized; and
at least one electrically insulating seal element engaging an outer surface of the arc chamber body for impeding material from exiting the chamber interior through the at least one access opening of the arc chamber body;
wherein said at least one electrically insulating seal element comprises Boron Nitride (BN) material.

2. The ion source of claim 1, wherein said Boron Nitride (BN) material is a hot-pressed Boron Nitride ceramic.

3. The ion source of claim 1, wherein said Boron Nitride (BN) material has a density of at least 1.95 g/cc (0.0704 lb/in³).

4. The ion source of claim 1 wherein said at least one electrically insulating seal element comprises a body having an outer wall that abuts the chamber body and circumferentially bounds the access opening which passes through the wall of the arc chamber body.

5. The ion source of claim 1 wherein said at least one electrically insulating seal element includes two seal portions that mate along an engagement surface.

6. For use in an ion implanter, a method for sealing an ion source comprising:
generating ions in a chamber interior having an exit for allowing ions generated inside the chamber interior to exit an arc chamber body;
supporting a cathode within a cathode opening in spaced relation to chamber walls bounding the chamber interior for injecting ionizing electrons into the chamber interior;
sealing an outer surface of the arc chamber body for impeding material from exiting the chamber through a an opening in said arc chamber body by providing a ceramic body having a wall that abuts the chamber body and further defining one or more radially inner channels bounded by one or more inner walls spaced from a region occupied by a cathode support;
wherein said ceramic body comprises Boron Nitride (BN) material.

7. The ion source of claim 6, wherein said Boron Nitride (BN) material is a hot-pressed Boron Nitride ceramic.

8. The ion source of claim 6, wherein said Boron Nitride (BN) material has a density of at least 1.95 g/cc (0.0704 lb/in³).

9. A seal for impeding gas flow from an arc chamber comprising:
a ceramic body including
i) a bounding wall having an outer surface for abutting an arc chamber body along a sealing surface and which bounds a throughpassage extending through the ceramic body for routing electrode energization signals into the arc chamber; and
ii) one or more one or more interior walls that define a cavity in the ceramic body and which communicates with a portion of an arc chamber interior and collects material in the arc chamber interior, wherein said ceramic body comprises Boron Nitride (BN) material.

10. The ion source of claim 9, wherein said Boron Nitride (BN) material is a hot-pressed Boron Nitride ceramic.

11. The ion source of claim 9, wherein said Boron Nitride (BN) material has a density of at least 1.95 g/cc (0.0704 lb/in³).

12. The seal of claim 9, wherein the ceramic body is formed of two parts that mate along a contact surface.
